(19) United States
(12) Patent Application Publication
(10) Pub. No.: US 2005/0196934 A1
(43) Pub. Date: Sep. 8, 2005

(54) SOI substrate and method of manufacturing the same

(75) Inventors: Koichi Tazoe, Hadano-shi (JP); Nobuhiko Sato, Sagamihara-shi (JP)

Correspondence Address: FITZPATRICK CELLA HARPER & SCINTO, 30 ROCKEFELLER PLAZA, NEW YORK, NY, 10112, US

(73) Assignee: Canon Kabushiki Kaisha, Tokyo (JP)

(21) Appl. No.: 11/055,167

(22) Filed: Feb. 11, 2005

(30) Foreign Application Priority Data
Feb. 16, 2004 (JP) 2004-038817

(51) Int. Cl. H01L 27/01

(52) U.S. Cl. 438/409

(57) ABSTRACT

A SOI substrate manufacturing method includes steps of preparing a substrate having a non-porous semiconductor layer on a porous portion, and executing an oxidation process for the substrate to at least partially oxidize the porous portion and change it to a buried oxide layer.

### FIELD OF THE INVENTION

The present invention relates to a SOI (Semiconductor On Insulator or Silicon On Insulator) substrate and a method of manufacturing the same.

### BACKGROUND OF THE INVENTION

A substrate having a semiconductor layer such as a silicon layer on an insulating layer is known as a SOI substrate. Several methods are known as SOI substrate manufacturing methods.

Japanese Patent Laid-Open No. 7-263538 discloses a method of improving the quality of a buried oxide layer in a SOI substrate or increasing the thickness of the buried oxide layer. More specifically, this reference discloses a method of increasing the thickness of a buried oxide layer formed in an SIMOX substrate (SOI substrate by SIMOX) and decreasing pinholes in the buried oxide layer or increasing the planarity of the interface between the buried oxide layer and a single-crystal silicon layer on it. In the method described in this reference, after oxygen ions are implanted in a single-crystal silicon substrate, annealing is executed in an inert gas atmosphere to form a buried oxide layer. The single-crystal silicon layer on the surface is isolated by the buried oxide layer.

In this method, after the thickness of the buried oxide layer is changed by annealing to a theoretical thickness calculated by the oxygen ion implantation amount, an oxidation process is executed for the substrate in a high-temperature oxygen atmosphere. In high-temperature oxidation after annealing, oxygen at a concentration of more than 1% is supplied to oxidize the substrate at a temperature from 1,150° C. (inclusive) to the melting point (exclusive) of the single-crystal silicon substrate, thereby forming an oxide layer on the buried oxide layer. With this process, the thickness of the buried oxide layer increases. Accordingly, pinholes in the original buried oxide layer are mended, and the three-dimensional pattern on the interface of the buried oxide layer is planarized. This high-temperature oxidation process is called ITOX (Internal Thermal Oxidation).

Japanese Patent Laid-Open No. 8-222715 discloses a bonding method. In the method disclosed in this reference, a surface active silicon-layer-side single-crystal silicon substrate having no surface oxide layer is bonded to a base-side single-crystal silicon substrate having a surface oxide layer with a thickness of 100 nm or less, and bonding is ended by annealing. Next, the surface of the surface active silicon-layer-side single-crystal silicon is polished to form an active layer having a thickness of about 1.0 μm. The SOI substrate thus obtained is subjected to an oxidation process in an O₂ gas atmosphere at a concentration of more than 1% at a temperature from 1,150° C. (inclusive) to the melting point (exclusive) of the substrate for several hrs. According to the reference, an oxide layer is further formed on the original buried oxide layer (original surface oxide layer). Hence, voids in the bonding interface decrease, and the bonding strength is equal to that of a bulk. Additionally, according to this reference, the bonding interface level density can be decreased to almost the same value as that of a bulk.

The techniques disclosed in Japanese Patent Laid-Open Nos. 7-263538 and 8-222715 can be regarded as a quality improvement of a buried oxide layer in a SOI substrate.

Ogura (Appl. Phys. Lett. 82 (2003) 4480) has reported that a structure with a single-crystal Si layer on an SiO₂ layer can be formed on a wafer surface by ion-implanting He as a light element and then executing annealing in an Ar/O₂ atmosphere (Ar/O₂ ratio=100/(1 to 20)) at 1,340° C. for 4 hrs.

The above-described SOI substrate manufacturing methods have unsolved problems. In the bonding method, the degree of freedom in determining the thicknesses of the SOI layer and BOX (Buried Oxide) layer is high. However, the cost readily increases because two wafers are used. Although wafer reuse is one solution, a recycle step is essential for wafer reuse. Hence, the material cost equals at least one wafer+recycle cost.

From the viewpoint of material cost, SIMOX is more advantageous because only one wafer is necessary. However, as for the quality of a resultant SOI substrate, the density of crystal defects called threading dislocation and the magnitude of micro-roughness in the SOI layer surface or the interface between the SOI layer and the buried oxide layer can pose problems in application to a device process. Especially, when the micropatterning progresses, and the degree of integration increases, these problems greatly affect the yield of circuits. To overcome these problems of SIMOX, ITOX has been proposed.

Application of ITOX to SIMOX has been effective to some extent but unable to sufficiently reduce the crystal defects and surface roughness. Crystal defects are feared to be a problem unique to ion implantation. When both the cost and quality are taken into consideration, a SOI wafer manufacturing method using neither ion implantation nor two wafers is preferable. Application of ITOX to a bonded SOI cannot solve the problem of use of two wafers.

A CZ wafer has a regular octagonal cavity called COP with a size of about 10² nm. When a SOI layer is formed by a surface layer of a CZ wafer, this portion forms a defect called an HF defect in the SOI layer. It is a killer defect in device manufacturing, as is known. As a measure against this defect, a CZ wafer which is made free from COP by decreasing the oxygen concentration is used. However, in annealing at more than 1,300° C. unique to the SIMOX process, a slip is readily introduced.

As another method, an epitaxial growth layer is formed on the surface of a CZ wafer, and whole or part of this layer is used as a SOI layer. However, this method is disadvantageous in terms of cost because the epitaxial growth step must be executed in addition to the ion implantation step.

In either prior art, high-temperature annealing is executed after ion implantation. For example, as is reported, in oxygen ion implantation, threading dislocation is generated in the SOI layer. Even in hydrogen ion implantation, crystal defects with a high density are introduced near the ion-implanted layer by annealing. That is, a problem remains unsolved in control of defect density.

In addition, ion implantation is normally executed after a silicon oxide layer having an amorphous structure is formed to prevent ion channeling. For this reason, the number of steps may increase.

### SUMMARY OF THE INVENTION

The present invention has been made on the basis of recognition of the above-described problems, and the object of a SOI substrate manufacturing method of the present invention is to, e.g., manufacture a SOI substrate by a simple process easy to reduce the cost.

A SOI substrate according to the present invention is, e.g., a SOI substrate which can be manufactured by the above-described manufacturing method, and has as its object to provide a SOI substrate in which the permittivity of a buried insulating layer is reduced.

A SOI substrate manufacturing method according to the present invention comprises a preparation step of preparing a substrate having a non-porous semiconductor layer on a porous portion, and an oxidation step of executing an oxidation process for the substrate to oxidize at least a part of the porous portion such that the porous portion changes to a buried oxide layer.

According to a preferred aspect of the present invention, the oxidation step can be executed in an atmosphere containing oxygen within a temperature range from 1,150° C. (inclusive) to a melting point (exclusive) of the substrate.

According to a preferred aspect of the present invention, the oxidation step can be executed under a condition that a part of the non-porous semiconductor layer is kept unoxidized after the oxidation step.

According to a preferred aspect of the present invention, the oxidation step can be executed under a condition that some pores in the porous portion remains after the oxidation step.

According to a preferred aspect of the present invention, the preparation step can comprise steps of forming a porous layer on a semiconductor substrate, and forming, on the porous layer, the non-porous semiconductor layer serving as a SOI layer. Alternatively, the preparation step can comprise steps of forming a porous layer on a semiconductor substrate, oxidizing a surface layer of the porous layer to form an oxide layer, removing the oxidized surface layer of the porous layer, and forming, on the porous layer, the non-porous semiconductor layer serving as a SOI layer.

According to a preferred aspect of the present invention, the non-porous semiconductor layer can contain silicon.

According to a preferred aspect of the present invention, the semiconductor substrate can be a silicon substrate, and the non-porous semiconductor layer can be a layer containing silicon.

A SOI substrate according to the present invention comprises an insulator, and a non-porous semiconductor layer arranged on the insulator, the insulator containing pores.

According to a preferred aspect of the present invention, the insulator can be buried in the SOI substrate.

According to a preferred aspect of the present invention, a stacking fault density of the non-porous semiconductor layer can be less than 10 pieces/cm².

According to the SOI substrate manufacturing method of the present invention, for example, the cost can easily be reduced by a simple process.

According to the SOI substrate of the present invention, for example, a SOI substrate in which the permittivity of the buried insulating layer is reduced is provided.

Other features and advantages of the present invention will be apparent from the following description taken in conjunction with the accompanying drawings, in which like reference characters designate the same or similar parts throughout the figures thereof.

### BRIEF DESCRIPTION OF THE DRAWINGS

The accompanying drawings, which are incorporated in and constitute a part of the specification, illustrate embodiments of the invention and, together with the description, serve to explain the principles of the invention.

FIGS. 1A to 1D are schematic sectional views showing a SOI (Semiconductor On Insulator or Silicon On Insulator) substrate manufacturing method according to a preferred embodiment of the present invention; and

FIGS. 2A and 2B are schematic views showing changes in a semiconductor layer 3 and porous layer 2 by the high-temperature oxidation step.

### DETAILED DESCRIPTION OF THE PREFERRED EMBODIMENT

A preferred embodiment of the present invention will be described below with reference to the accompanying drawings.

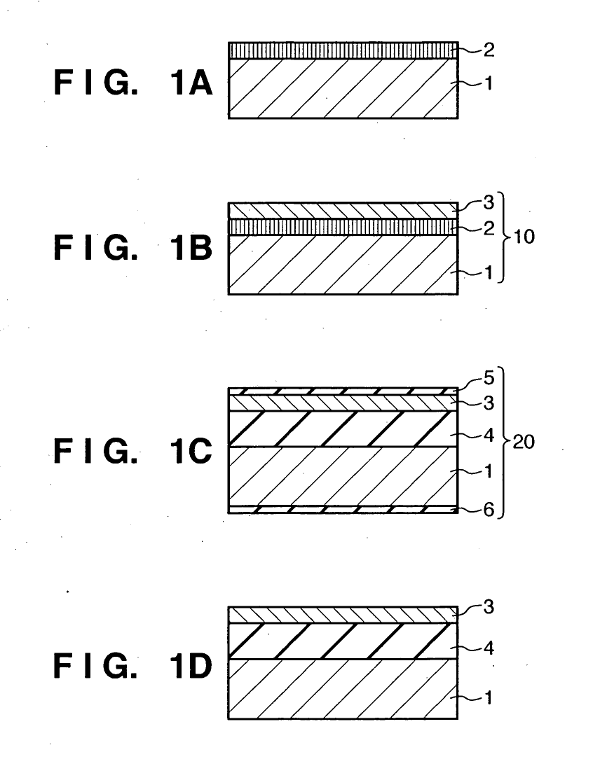

FIGS. 1A to 1D are schematic sectional views showing a SOI (Semiconductor On Insulator or Silicon On Insulator) substrate manufacturing method according to a preferred embodiment of the present invention.

In the porous layer formation step shown in FIG. 1A, a current is supplied through a silicon substrate 1 such as a single-crystal silicon substrate in an anodizing solution such as a solution containing HF (hydrogen fluoride), thereby forming, on the surface of the substrate 1, a porous layer (porous portion) 2 having micropores with a size of several nm preferably at a density of about 10¹¹ pieces/cm². When the composition or ion concentration of the anodizing solution such as a solution containing HF or the current value is changed, the porosity or thickness of the porous layer 2 can be adjusted. For example, when the HF concentration is 30%, and the current application time is 8 sec, the thickness of the porous layer can be about 200 nm, and the porosity can be about 40%. The structure depending on the anodizing process, including the pore size, porosity, and thickness of the porous layer 2, is determined in consideration of the required layer structure.

The porous layer may be formed by a method except anodizing. For example, a porous layer can be formed by dry-etching or wet-etching the substrate 1 through a mask having a number of micropores.

In the SOI layer formation step shown in FIG. 1B, a semiconductor layer 3 such as a single-crystal silicon layer serving as a prospective SOI layer in the subsequent step is formed on the porous layer 2. An example of the method of forming a single-crystal silicon layer serving as the semiconductor layer 3 is epitaxial growth by CVD. More specifically, in this method, high-temperature annealing is executed while supplying a gas containing silicon into a chamber in which the single-crystal silicon substrate 1 having the porous layer 2 is loaded. Accordingly, the single-crystal silicon layer 3 can be epitaxially grown on the porous layer 2. The thickness of the single-crystal silicon layer 3 can arbitrarily be adjusted by changing the process conditions. For example, when the substrate is processed in a gas atmosphere containing SiH₂Cl₂ at a flow rate of 80 to 300 sccm and H₂ at a flow rate of 40 L/min at 900° C. for 1 min, an epitaxial silicon layer having a thickness of 60 to 200 nm can be obtained. As the semiconductor layer 3, generally, a single-crystal silicon layer is preferable. In addition, a layer formed by doping, e.g., germanium in silicon is also useful. The semiconductor layer 3 different from the material of the substrate 1 can be formed by various methods such as CVD.

In the high-temperature oxidation step (high-temperature annealing) shown in FIG. 1C, a substrate 10 which has undergone the SOI layer formation step shown in FIG. 1B is heated in an atmosphere containing oxygen within a temperature range from 1,150° C. (inclusive) to the melting point (exclusive) of the substrate 10 for several hrs. At this time, the O₂ gas concentration can be set within the range of 1% to 100%. By the high-temperature oxidation step, the O₂ gas diffuses from the surface of the substrate 10 into its interior and reacts with silicon as the material of the porous layer 2. With this process, at least a part of the porous layer 2 is oxidized to form a buried oxide layer 4.

Important conditions in executing the high-temperature oxidation step are as follows.

(Condition 1) The porous silicon layer 2 is wholly or partially oxidized by the high-temperature oxidation step so that the semiconductor layer 3 is isolated from the substrate 1.

(Condition 2) At least a part of the semiconductor layer 3 remains as an unoxidized layer after the high-temperature oxidation step.

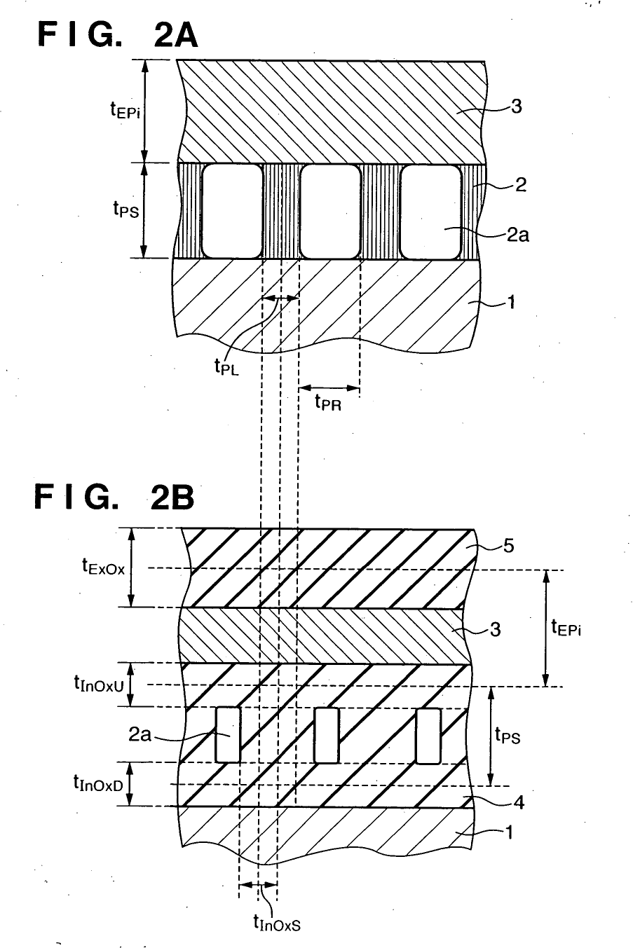

FIGS. 2A and 2B are schematic views showing changes in the semiconductor layer 3 and porous layer 2 by the high-temperature oxidation step. FIG. 2A shows the structure before the high-temperature oxidation step is executed (corresponding to FIG. 1B). FIG. 2B shows the structure after the high-temperature oxidation step is executed (corresponding to FIG. 1C). Referring to FIGS. 2A and 2B, t_{EPi} indicates the thickness of the semiconductor layer 3 before execution of the high-temperature oxidation step; t_{PS}, the thickness of the porous layer 2 before execution of the high-temperature oxidation step; t_{PR}, the width of a pore in the porous layer 2 before execution of the high-temperature oxidation step; t_{PL} the pore interval width (thickness of pore wall) in the porous layer 2 before execution of the high-temperature oxidation step; t_{Ex0x}, the thickness of an oxide layer formed on the surface of the substrate; and t_{In0xS}, t_{In0xU}, and t_{In0xD}, the sizes representing the structure of the buried oxide layer 4 formed by the high-temperature oxidation. More specifically, t_{In0xS} is ½ the interval between pores 2a, t_{In0xU} is the distance from the upper end of the pore 2a to the upper end of the buried oxide layer 4, and t_{In0xD} is the distance from the lower end of the pore 2a to the lower end of the buried oxide layer 4.

Condition 1 is expressed by t_{PL}≦0.44t_{In0xS}×2. Condition 2 is expressed by t_{EPi}>0.44t_{Ex0x}+0.44t_{In0xU}. When the process is determined such that conditions 1 and 2 are satisfied, a SOI structure can be obtained.

If condition 1 is not satisfied, a portion which electrically connects the semiconductor layer 3 to the substrate 1 is formed at part of the buried oxide layer 4. That is, if condition 1 is not satisfied, there is a possibility that the semiconductor layer 3 is not completely isolated from the substrate 1. However, when t_{In0xU} and t_{In0xD} are sufficiently large, the semiconductor layer 3 is isolated from the substrate 1 by the portions indicated by t_{In0xU} and t_{In0xD}. If condition 2 is not satisfied, the semiconductor layer 3 serving as a SOI layer is entirely oxidized.

When condition 1 is satisfied, the buried insulating layer 4 can have a structure having no pores 2a or a structure having the pores 2a. In the buried insulating layer 4 having the structure with the pores 2a, since an oxide and pores are mixed, the permittivity is higher than the buried insulating layer having no pores 2a. That is, when the occupation ratio (porosity) of the pores 2a is increased, the permittivity can be made low. As a result, the parasitic capacitance can be made lower than in a normal SOI structure. The permittivity of the porous buried oxide layer is almost proportional to the porosity of the buried oxide layer. When the porosity is controlled, the permittivity of the buried insulating layer can be controlled within the range of the permittivity of SiO₂ to the permittivity of air (1).

In the oxide layer removing step shown in FIG. 1D, of an oxide layer 5 formed on the front surface of a substrate 20 obtained by the high-temperature oxidation step shown in FIG. 1C and an oxide layer 6 formed on the back surface of the substrate 20, at least the oxide layer 5 formed on the front surface is removed. The process is easier when both the oxide layer 5 on the front surface and the oxide layer 6 on the back surface are moved. The oxide layer 5 and oxide layer 6 are moved by, e.g., dipping the substrate 20 in a solution containing hydrogen fluoride. With this above process, a SOI substrate or SOI structure having the semiconductor layer 3 on the buried oxide layer 4 is obtained.

In the above embodiment, the SOI layer formation step (FIG. 1B) is executed next to the porous layer formation step (FIG. 1A). Instead, the surface layer of the porous layer 2 may be oxidized next to the porous layer formation step. The thus formed oxide layer on the surface layer of the substrate is removed by using a solution containing hydrogen fluoride. After that, the SOI layer formation step is executed to form the semiconductor layer 3 on the surface of the porous layer 2. For example, when the porous silicon layer 2 is oxidized at a low temperature of 400° C., the surface layer of the porous silicon layer 2 is oxidized by several nm. When the silicon oxide layer on the oxidized surface layer is HF-processed, silicon can be exposed to the surface again. Next, when silicon is epitaxially grown on the silicon layer, the semiconductor layer (epitaxial silicon layer) 3 can be formed. When the porous silicon layer 2 is oxidized after anodizing, deformation of the porous silicon layer 2 in the high-temperature oxidation step can be relaxed, and the time of the high-temperature oxidation step can be shortened.

An example to which the present invention is applied will be described. In this example, a SOI substrate having a 53-nm thick SOI layer on a 173-nm buried insulating layer is manufactured.

First, in the porous layer formation step (FIG. 1A), a current of 5.12 A was supplied in a 30% HF solution for 2 sec by using a single-crystal silicon substrate 1 as an anode. With this process, a 48.5-nm thick porous silicon layer 2 was formed on the surface of the substrate 1. The porosity of the porous silicon layer 2 was 40%.

In the SOI layer formation step (FIG. 1B), the substrate with the porous silicon layer 2 exposed to the surface was held and processed in a chamber, to which SiH₂Cl₂=20 sccm and H₂=25 slm were supplied, at 900° C. for 260 sec to form a 260-nm thick epitaxial silicon layer 3.

In the high-temperature oxidation step (FIG. 1C), the substrate was processed in a 20% O₂ atmosphere at 1,340° C. for 4 hrs. With this process, the porous silicon layer 2 was oxidized to form a 173-nm thick buried insulating layer. Simultaneously, a 400-nm thick oxide layer 5 was formed on the surface of the substrate.

In the oxide layer removing step (FIG. 1D), the oxide layers on the front surface and back surface of the substrate were removed by the HF process so that a SOI substrate was obtained. When the film thicknesses were measured by using a spectral ellipsometer, the obtained SOI substrate had a 53-nm thick SOI layer on a 173-nm buried insulating layer, as planned. When the section of the SOI substrate was observed by a TEM image, the pore walls in the porous layer 2 had been oxidized by the high-temperature oxidation step. Cu decoration indicated that there were few BOX (buried oxide layer) pinholes in number. Hence, the epitaxial silicon layer 3 was found to be completely isolated by the buried insulating layer 4. In addition, the stacking fault density of the semiconductor layer 3 was lower than 10 pieces/cm².

According to the SOI substrate manufacturing method of the preferred embodiment of the present invention, the crystal defects are decreased as compared to SIMOX because no ion implantation is executed. The number of material substrates is one, and the number of steps is largely decreased as compared to the bonding method. Hence, the manufacturing cost can be reduced. The small number of steps is advantageous even in suppressing facility investment or quality control. In the bonding method, typically, after substrates are bonded, a step of splitting the bonded substrate stack into two parts by using a separation layer is executed. For this reason, a process for recovering the planarity on the separation interface is important. According to the SOI substrate manufacturing method of the present invention, however, such a process is unnecessary.

In the SOI substrate manufacturing method according to the preferred embodiment of the present invention, when the SOI layer is formed by epitaxial growth, HF defects such as COP caused by defects unique to a wafer manufactured by the CZ method can be reduced.

According to the SOI substrate according to the preferred embodiment of the present invention, when pores are left in the buried insulating layer in the high-temperature oxidation step, the permittivity of the buried insulating layer can be made low. Accordingly, the parasitic capacitance between the substrate and the SOI substrate can be reduced without forming a thick buried insulating layer. In addition, the porous buried insulating layer also solves the problem of warping of the SOI substrate, which can occur when a thick buried insulating layer is formed.

As many apparently widely different embodiments of the present invention can be made without departing from the spirit and scope thereof, it is to be understood that the invention is not limited to the specific embodiments thereof except as defined in the claims.

### CLAIM OF PRIORITY

This application claims priority from Japanese Patent Application No. 2004-038817 filed on Feb. 16, 2004, the entire contents of which are hereby incorporated by reference herein.

1. A SOI substrate manufacturing method comprising:
a preparation step of preparing a substrate having a non-porous semiconductor layer on a porous portion; and
an oxidation step of executing an oxidation process for the substrate to oxidize at least a part of the porous portion such that the porous portion changes to a buried oxide layer.

2. The method according to claim 1, wherein the oxidation step is executed in an atmosphere containing oxygen within a temperature range from 1,150° C. (inclusive) to a melting point (exclusive) of the substrate.

3. The method according to claim 1, wherein the oxidation step is executed under a condition that a part of the non-porous semiconductor layer is kept unoxidized after the oxidation step.

4. The method according to claim 1, wherein the oxidation step is executed under a condition that some pores in the porous portion remains after the oxidation step.

5. The method according to claim 1, wherein the preparation step comprises steps of
forming a porous layer on a semiconductor substrate, and
forming, on the porous layer, the non-porous semiconductor layer serving as a SOI layer.

6. The method according to claim 1, wherein the preparation step comprises steps of
forming a porous layer on a semiconductor substrate,
oxidizing a surface layer of the porous layer to form an oxide layer,
removing the oxidized surface layer of the porous layer, and
forming, on the porous layer, the non-porous semiconductor layer serving as a SOI layer.

7. The method according to claim 1, wherein the non-porous semiconductor layer contains silicon.

8. The method according to claim 5, wherein the semiconductor substrate is a silicon substrate, and the non-porous semiconductor layer contains silicon.

9. A SOI substrate comprising:
an insulator; and
a non-porous semiconductor layer arranged on said insulator,
said insulator containing pores.

10. The substrate according to claim 9, wherein said insulator is buried in the SOI substrate.

11. The substrate according to claim 9, wherein a stacking fault density of said non-porous semiconductor layer is less than 10 pieces/cm².
